(19) United States
(12) Patent Application Publication
(10) Pub. No.: US 2017/0067778 A1
(43) Pub. Date: Mar. 9, 2017

(54) SENSOR AND SENSOR SYSTEM

(71) Applicant: Kabushiki Kaisha Toshiba, Minato-ku (JP)

(72) Inventors: Keiji SUGI, Fujisawa (JP); Tomio ONO, Yokohama (JP); Toshiya YONEHARA, Kawasaki (JP)

(73) Assignee: Kabushiki Kaisha Toshiba, Minato-ku (JP)

(21) Appl. No.: 15/254,372

(22) Filed: Sep. 1, 2016

(30) Foreign Application Priority Data
Sep. 8, 2015 (JP) 2015-176657

(51) Int. Cl. G01J 1/44; H01L 31/173

(52) U.S. Cl. CPC G01J 1/44; H01L 31/173

(57) ABSTRACT

According to one embodiment, a sensor includes a first light-emitting region, a second light-emitting region, and a light receiving element. At least one of at least a portion of a first light or at least a portion of a second light is incident on the light receiving element. The first light is emitted from the first light-emitting region. The second light is emitted from the second light-emitting region. A second position of the second light-emitting region in a first direction is between a first position of the first light-emitting region in the first direction and a light receiving position of the light receiving element in the first direction. The first direction is from the first light-emitting region toward the second light-emitting region.

### CROSS-REFERENCE TO RELATED APPLICATIONS

This application is based upon and claims the benefit of priority from Japanese Patent Application No. 2015-176657, filed on Sep. 8, 2015; the entire contents of which are incorporated herein by reference.

### FIELD

Embodiments described herein relate generally to a sensor and a sensor system.

### BACKGROUND

There is a sensor that irradiates light on a sensing object and senses the light reflected by the sensing object. It is desirable for the sensor to have high sensing precision.

### BRIEF DESCRIPTION OF THE DRAWINGS

FIG. 1A and FIG. 1B are schematic views illustrating a sensor according to a first embodiment;

FIG. 2A and FIG. 2B are schematic cross-sectional views illustrating operations of the sensor according to the first embodiment;

FIG. 3 is a flowchart illustrating operations of the sensor according to the first embodiment;

FIG. 4A to FIG. 4C are schematic cross-sectional views illustrating portions of the sensor according to the first embodiment;

FIG. 5 is a schematic cross-sectional view illustrating another operation of the sensor according to the first embodiment;

FIG. 6A to FIG. 6C are schematic cross-sectional views illustrating other sensors according to the first embodiment;

FIG. 7A to FIG. 7C are schematic plan views illustrating sensors according to a second embodiment;

FIG. 8A to FIG. 8C are schematic plan views illustrating other sensors according to the second embodiment;

FIG. 9A and FIG. 9B are schematic plan views illustrating other sensors according to the second embodiment;

FIG. 10A to FIG. 10D are schematic plan views illustrating other sensors according to a third embodiment;

FIG. 11 is a schematic plan view illustrating a sensor according to a fourth embodiment; and

FIG. 12 is a schematic view illustrating a sensor system according to a fifth embodiment.

### DETAILED DESCRIPTION

According to one embodiment, a sensor includes a first light-emitting region, a second light-emitting region, and a light receiving element. At least one of at least a portion of a first light or at least a portion of a second light is incident on the light receiving element. The first light is emitted from the first light-emitting region. The second light is emitted from the second light-emitting region. A second position of the second light-emitting region in a first direction is between a first position of the first light-emitting region in the first direction and a light receiving position of the light receiving element in the first direction. The first direction is from the first light-emitting region toward the second light-emitting region.

Various embodiments will be described hereinafter with reference to the accompanying drawings. Like members are labeled with like reference numerals, the detailed description is appropriately omitted, and different portions are described. The drawings are schematic and conceptual; and the relationships between the thickness and width of portions, the proportions of sizes among portions, etc., are not necessarily the same as the actual values thereof. Further, the dimensions and proportions may be illustrated differently among drawings, even for identical portions.

### First Embodiment

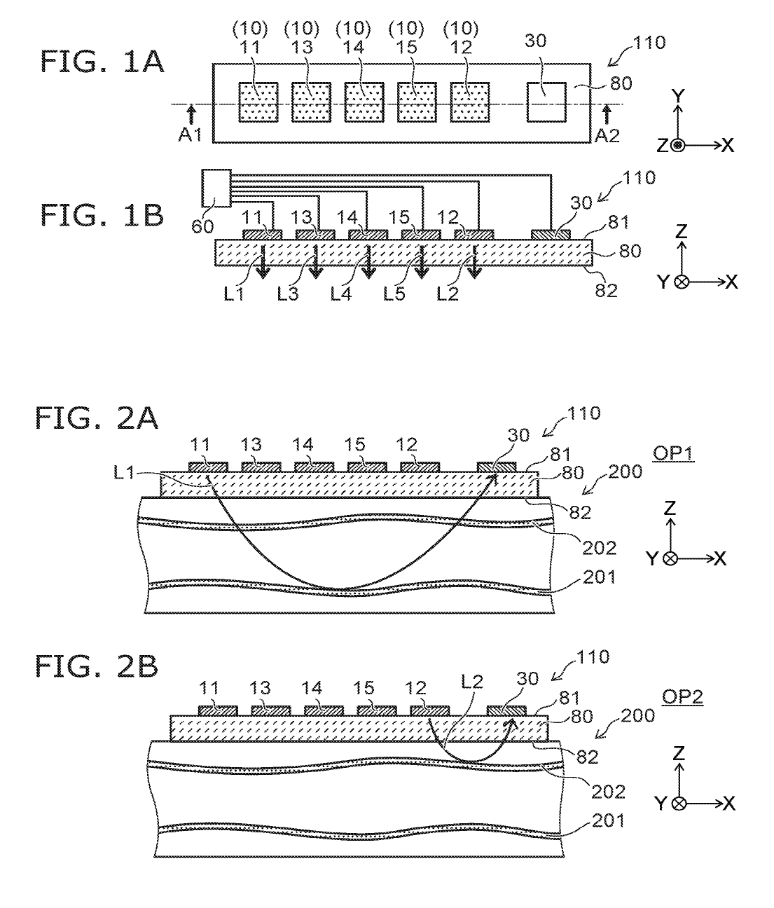

FIG. 1A and FIG. 1B are schematic views illustrating a sensor according to a first embodiment. FIG. 1A is a plan view. FIG. 1B is a line A1-A2 cross-sectional view of FIG. 1A.

As shown in FIG. 1A, the sensor 110 according to the embodiment includes multiple light-emitting regions 10 (e.g., first to fifth light-emitting regions 11 to 15, etc.) and a light receiving element 30. In the example, the sensor 110 further includes a substrate 80. For example, the sensor 110 can sense a biological signal (e.g., a pulse wave, blood oxygen concentration, etc.).

As described below, light (a first light) is emitted from the first light-emitting region 11 and irradiated on a sensing object (e.g., a living body); and light (a second light) is emitted from a second light-emitting region 12 and irradiated on the sensing object. This light is reflected inside the sensing object. For example, the first light and second light are scattered. The light that undergoes at least one of reflection or scattering is incident on the light receiving element 30. In other words, at least one of at least a portion of the first light or at least a portion of the second light is incident on the light receiving element 30.

A direction from the first light-emitting region 11 toward the second light-emitting region 12 is taken as a first direction. The first direction is taken as an X-axis direction. One direction perpendicular to the X-axis direction is taken as a Y-axis direction. A direction perpendicular to the X-axis direction and the Y-axis direction is taken as a Z-axis direction.

As shown in FIG. 1B, the substrate 80 has a first surface 81 and a second surface 82. The first surface 81 is along the X-axis direction and the Y-axis direction. The second surface 82 is the surface on the side opposite to the first surface 81. For example, the first surface 81 is the upper surface; and the second surface 82 is the lower surface. For example, the first surface 81 is substantially perpendicular to the Z-axis direction. The substrate 80 may be flexible. For example, the first surface 81 may be a curved surface.

The multiple light-emitting regions 10 are provided in the first surface 81. For example, the multiple light-emitting regions 10 are provided in the X-Y plane. In the example, the light receiving element 30 also is provided at the first surface 81. As described below, the light receiving element 30 may be provided at the second surface 82.

The position (a second position) of the second light-emitting region 12 in the first direction (a direction from the first light-emitting region 11 toward the second light-emitting region 12, i.e., in the example, the X-axis direction) is between the position (a first position) of the first light-emitting region 11 in the first direction and the position (a light receiving position) of the light receiving element 30 in the first direction.

In other words, the first light-emitting region 11 is distal to the light receiving element 30. The second light-emitting region 12 is proximal to the light receiving element 30. The distance between the first light-emitting region 11 and the light receiving element 30 is longer than the distance between the second light-emitting region 12 and the light receiving element 30.

The second light-emitting region 12 is provided between the light receiving element 30 and the first light-emitting region 11. In the example, the third light-emitting region 13 is provided between the first light-emitting region 11 and the second light-emitting region 12. The fourth light-emitting region 14 is provided between the third light-emitting region 13 and the second light-emitting region 12. The fifth light-emitting region 15 is provided between the fourth light-emitting region 14 and the second light-emitting region 12.

In the embodiment, the multiple light-emitting regions 10 (e.g., the first to fifth light-emitting regions 11 to 15) do not overlap the light receiving element 30 in the Z-axis direction (one direction perpendicular to the first direction).

The first to fifth light-emitting regions 11 to 15 respectively emit first to fifth light L1 to L5. In the example, the substrate 80 is light-transmissive. The first to fifth light L1 to L5 passes through the substrate 80. The light that passes through the substrate 80 is incident on the sensing object. The light that is reflected (or scattered) by the sensing object passes through the substrate 80 and is incident on the light receiving element 30. The sensing object is sensed using the sense signal obtained by the light receiving element 30.

In the example as shown in FIG. 1B, the sensor 110 includes a controller 60. The controller 60 is connected to the multiple light-emitting regions 10. The controller 60 drives the multiple light-emitting regions 10. The controller 60 may be connected to the light receiving element 30. For example, the sense signal that is obtained by the light receiving element 30 is input to the controller 60. The controller 60 may process the sense signal obtained by the light receiving element 30.

For example, the light that is emitted from the first light-emitting region 11 which is distal to the light receiving element 30 is incident on the light receiving element 30 after passing through a distal position of the sensing object. On the other hand, the light that is emitted from the second light-emitting region 12 which is proximal to the light receiving element 30 is incident on the light receiving element 30 after passing through a proximal position of the sensing object. The sensing of the multiple positions having mutually-different distances from the sensor 110 can be implemented with high precision by using the multiple light-emitting regions 10 that have mutually-different distances from the light receiving element 30.

For example, the sensor 110 according to the embodiment is used to sense a living body. The living body includes an object (e.g., a blood vessel, etc.). The sensor 110 is disposed at the vicinity of the surface of the living body. The light that is emitted from the multiple light-emitting regions 10 enters the living body. The light that enters is reflected (scattered) by the blood vessel, etc., inside the living body. The light that is reflected (scattered) is incident on the light receiving element 30. For example, the living body has a position inside the living body proximal to the surface (a shallow position), and a position inside the living body distal to the surface (a deep position). For example, there are cases where the density of the blood vessels at the shallow position is lower than the density of the blood vessels existing at the deep position. In such a case, for example, the sensing is performed by using the light of the first light-emitting region 11 that passes through the deep position having the high density. Thereby, the state of the blood vessels at a desired position can be sensed with high precision. In other words, the precision of the sensing can be increased by sensing the information of the position at the desired depth using the light-emitting region 10 corresponding to the depth.

For example, the second light-emitting region 12 does not emit light when the first light-emitting region 11 is emitting light. Thereby, the effects of positions at depths that are not the target depth are suppressed. Thereby, the state of the object (the blood vessel) at the position of the target depth can be sensed with high precision.

Conversely, for example, the second light-emitting region 12 is caused to emit light; and the first light-emitting region 11 is caused to not emit light. Sensing is performed using the light of the second light-emitting region 12. Thereby, the state of the blood vessel at the shallow position can be sensed with high precision. In such a case, the effects of the deep position are suppressed because the first light-emitting region 11 does not emit light. Thereby, the state of the object (the blood vessel) at the shallow position which is the target can be sensed with high precision.

On the other hand, for example, there is a first reference example in which the distances are the same between the light receiving element and the multiple light-emitting regions. In the reference example, the multiple light-emitting regions are arranged on a concentric circle around the light receiving element. In the reference example, because the distances are the same between the light receiving element and the multiple light-emitting regions, it is difficult to obtain the information at positions of different depths with high precision.

In the embodiment, the second light-emitting region 12 is provided between the first light-emitting region 11 and the light receiving element 30. In other words, in one direction, the first light-emitting region 11 and the second light-emitting region 12 are provided at multiple positions having mutually-different distances from the light receiving element 30. By using such a first light-emitting region 11 and such a second light-emitting region 12, the information at positions of different depths can be obtained with high precision.

There are cases where the state of a designated blood vessel is examined as an examination of the living body. The position of the blood vessel from the surface of the living body may be different between the living bodies. For example, the thickness of layers of fat at the surface vicinity of the skin, etc., are different between living bodies. In such a case, the depth from the surface of the designated blood vessel is different between the living bodies. Even in such a case, by using the light-emitting regions corresponding to the different depths, the state of the designated blood vessel can be sensed with high precision.

There are also cases where the examination of the living body is performed continuously and constantly. In such a case, the examination is performed for a designated position inside the living body to reduce the burden. There are cases where the density of the blood vessels is low at the designated position. In such a case, sensing with high precision is possible by selectively sensing a region corresponding to the blood vessel as the object.

FIG. 2A and FIG. 2B are schematic cross-sectional views illustrating operations of the sensor according to the first embodiment.

FIG. 2A corresponds to a first operation OP1. FIG. 2B corresponds to a second operation OP2.

As shown in FIG. 2A, a living body 200 includes a first blood vessel 201 and a second blood vessel 202. The distance between the first blood vessel 201 and the substrate 80 is longer than the distance between the second blood vessel 202 and the substrate 80.

In the first operation OP1 shown in FIG. 2A, the first blood vessel 201 is the object of the sensing. In the first operation OP1, the first light-emitting region 11 is set to a light-emitting state (e.g., a first light-emitting state). The second light-emitting region 12 is set to a non-light-emitting state (e.g., a second non-light-emitting state). In the example, the third to fifth light-emitting regions 13 to 15 are set to the non-light-emitting state.

For the light-emitting regions 10 (in the example, the second to fifth light-emitting regions 12 to 15) in the non-light-emitting state, light is not emitted from the light-emitting regions 10. Or, the intensity of the light emitted from the light-emitting regions 10 (in the example, the second to fifth light-emitting regions 12 to 15) in the non-light-emitting state is lower than the intensity of the light emitted from the light-emitting region 10 (in the example, the first light-emitting region 11) in the light-emitting state. For example, the intensity of the light in the non-light-emitting state is not more than 1/10 of the intensity of the light in the light-emitting state.

In the second operation OP2 shown in FIG. 2B, the second blood vessel 202 is the object of the sensing. In the second operation OP2, the second light-emitting region 12 is set to the light-emitting state (a second light-emitting state). The first light-emitting region 11 is set to the non-light-emitting state. In the example, the third to fifth light-emitting regions 13 to 15 are set to the non-light-emitting state.

As shown in FIG. 2A and FIG. 2B, the light-emitting regions 10 are selected according to the object (the first blood vessel 201 or the second blood vessel 202). Thereby, the state of the object can be sensed with high precision.

For example, such a first operation OP1 and such a second operation OP2 may be implemented by the controller 60. An example of the operations of the controller 60 will now be described.

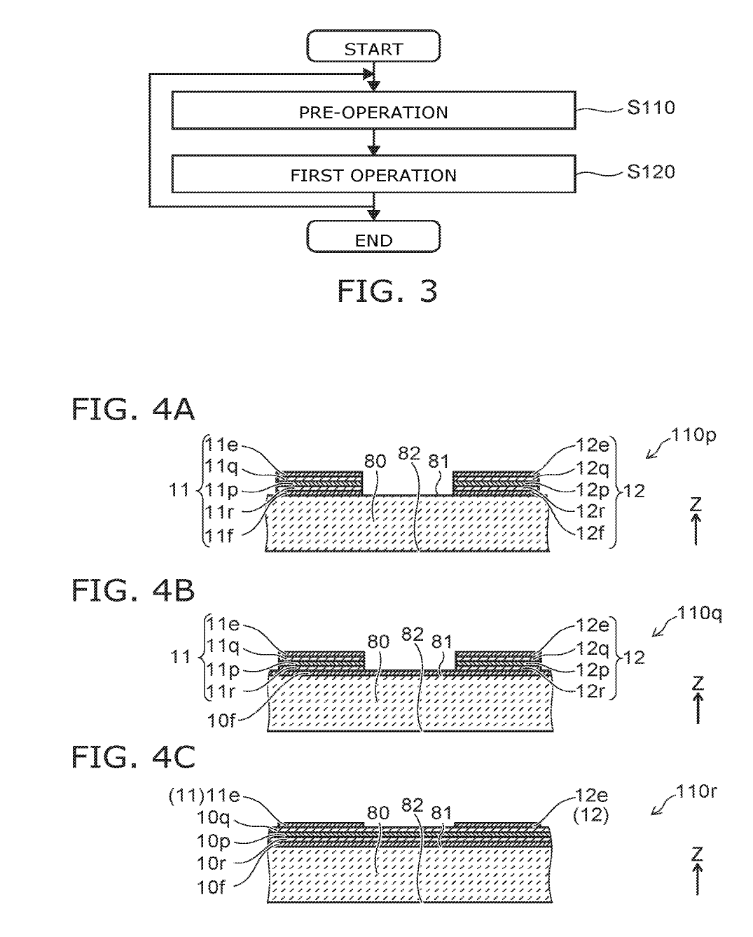

FIG. 3 is a flowchart illustrating operations of the sensor according to the first embodiment.

As shown in FIG. 3, the controller 60 implements a pre-operation (step S110). The pre-operation is, for example, a preparation operation. In the pre-operation, each of the multiple light-emitting regions 10 is set to the light-emitting state. For example, the multiple light-emitting regions 10 are set in order one at a time to the light-emitting state; and the light is sensed by the light receiving element 30 synchronously. For example, the state of the light is sensed for each of the multiple light-emitting regions 10 when the light-emitting region is in the light-emitting state and the other light-emitting regions 10 are in the non-light-emitting state.

For example, in the case where the object of the sensing is a blood vessel, the change (the signal) of the light has a pulse wave shape. The interval in which the amplitude of the pulse wave shape is large is designated; and the light-emitting regions 10 that are set to the light-emitting state in the interval are designated. For example, a threshold that relates to the amplitude of the pulse wave shape is determined; and the sensed amplitude is compared to the threshold. The interval in which the amplitude of the pulse wave shape is large is designated based on the comparison result. Thus, by the pre-operation, the light-emitting regions 10 for which high sensitivity is obtained for the target object (the blood vessel) are determined. In other words, the first light-emitting region 11 is determined from among the multiple light-emitting regions 10 based on the result of the pre-operation; and the second light-emitting region 12 is determined from among the multiple light-emitting regions 10 based on the result of the pre-operation.

Then, after the pre-operation, the controller 60 implements the first operation OP1 (step S120). In the first operation OP1, the first light-emitting region 11 that is determined based on the result of the pre-operation is in the light-emitting state (the first light-emitting state); and the second light-emitting region 12 that is determined based on the result of the pre-operation is in the non-light-emitting state (the second non-light-emitting state).

In other words, by the pre-operation, the light-emitting regions 10 that correspond to the object of the sensing (e.g., the blood vessel, etc.) are designated; and the light-emitting regions 10 that are designated are set to the light-emitting state. The other light-emitting regions 10 are set to the non-light-emitting state. Thereby, one object can be sensed with high precision.

As shown in FIG. 3, such operations may be implemented repeatedly. In other words, the pre-operation is implemented again after implementing the first operation OP1. Another first operation (i.e., the second operation OP2) may be implemented based on the result of the pre-operation that is implemented again. The second operation OP2 is implemented for the case of a different object, for the case where the relative positions of the sensor 110 and the object have moved, etc. In the second operation OP2 as well, high-precision sensing is performed.

In the sensor 110 according to the embodiment as recited above, a portion of the multiple light-emitting regions 10 is set to the light-emitting state according to the object of the examination; and the other light-emitting regions 10 are set to the non-light-emitting state. Thereby, high-precision sensing is possible.

On the other hand, there is a second reference example in which one light-emitting element and multiple sensing elements are provided. In the reference example, an imaging image is acquired by the multiple sensing elements; the position (the depth, etc.) of the blood vessel is designated based on the imaging image; and based on the result, for example, the components inside the blood vessel are sensed. In the reference example, complex image processing is performed; and the device (particularly, the processing circuit) is complex. Further, the second reference example is expensive because the multiple light receiving elements are arranged in a matrix configuration.

Further, in the second reference example, the light that is emitted from the one light-emitting element spreads over a wide range; and the imaging is performed using the light passing through the wide range. The light is scattered by the multiple objects (the blood vessels, etc.) existing in the wide range and is incident on the multiple light receiving elements. The light that is reflected (scattered) by each of the multiple objects also is incident on other objects and is further reflected (scattered). Therefore, the light that passes through the wide range is affected by the multiple objects. Therefore, in the second reference example, it is difficult to sense the designated object with high precision.

In the case where the object is a blood vessel, etc., the signal that is sensed has a pulse wave shape. The pulse wave changes temporally and is substantially periodic. In the case where such a pulse wave is generated by multiple objects within a wide range, a time delay of the pulse wave occurs due to different positions within the wide range. In other words, a temporal shift is superimposed onto the pulse wave according to the different positions of the objects (the blood vessels, etc.) existing in the wide range. The light is affected by the superimposition of the temporal shift. Such light reaches the multiple light receiving elements. Therefore, in the second reference example, high-precision sensing is difficult due to the effect of the temporal shift of the pulse wave.

Conversely, in the sensor 110 according to the embodiment, the light-emitting regions 10 that correspond to the target object (the blood vessel, etc.) are selectively set to the light-emitting state. Thereby, the effect of the temporal shift of the pulse wave is suppressed. Therefore, high-precision sensing is possible also when sensing the object of the pulse wave.

In the embodiment, complex image processing and the like are unnecessary; and the device is simple. Therefore, the cost can be reduced.

On the other hand, there is a third reference example in which a light receiving element overlaps multiple light-emitting regions in the Z-axis direction. At least a portion of the multiple light-emitting regions overlaps the light receiving element in the Z-axis direction. In such a case, a portion of the light receiving surface of the light receiving element is shielded by the light-emitting regions. Therefore, the light receiving element cannot be utilized sufficiently; and the sensing efficiency is insufficient. Therefore, in the third reference example, the increase of the sensing sensitivity is insufficient.

Conversely, in the embodiment, the multiple light-emitting regions 10 do not overlap the light receiving element 30 in the Z-axis direction. Therefore, the light receiving surface of the light receiving element 30 is not shielded by the light-emitting regions 10. The sensing efficiency is high because the light receiving element 30 can be utilized sufficiently. In the embodiment, the sensing sensitivity can be increased. Thereby, high-precision sensing is possible.

In the embodiment, the noise of the sensing can be reduced by using organic light-emitting layers as the multiple light-emitting regions 10. According to investigations by the inventor, it was found that the noise of the light radiated from the light-emitting regions including organic light-emitting layers is lower than the noise of the light radiated from light-emitting regions including inorganic light-emitting layers (e.g., a semiconductor crystal, etc.). For example, in the semiconductor crystal, the light is emitted by carriers recombining with a constant probability. It is considered that the noise corresponding to the fluctuation of the recombination in the semiconductor crystal occurs because the fluctuation of the recombination is relatively small.

Conversely, in the organic light-emitting layer, it is considered that the recombination is averaged temporally because the fluctuation of the compound included in the organic light-emitting layer is large. As a result, it is considered that the noise is low in the case where the organic light-emitting layer is used. In particular, in the case where the signal having the pulse wave shape is sensed, the pulse wave can be sensed with high precision by stably sensing the temporal change of the signal. By using light having low noise, the pulse wave can be sensed with high precision. The light that is radiated from the light-emitting regions including organic light-emitting layers is suited to applications that sense a sensing object in which a micro signal is output from a pulse wave, etc.

In the embodiment, the multiple light-emitting regions are provided; and the multiple light-emitting regions 10 are selectively set to the light-emitting state. Therefore, the driving time of each of the multiple light-emitting regions 10 is short. The driving life may be shorter for an organic light-emitting layer than for an inorganic light-emitting layer (e.g., a semiconductor crystal, etc.). In the embodiment, the driving time of each of the multiple light-emitting regions 10 is short when the multiple light-emitting regions 10 include organic light-emitting layers; therefore, the problem of the shortness of the driving life of the organic light-emitting layer is reduced.

An example in which the light-emitting region 10 includes an organic light-emitting layer will now be described.

FIG. 4A to FIG. 4C are schematic cross-sectional views illustrating portions of the sensor according to the first embodiment.

As shown in FIG. 4A, a first segment electrode 11e, a first counter electrode 11f, a first light-emitting layer lip, a first segment intermediate layer 11q, and a first counter intermediate layer 11r are provided in a sensor 110p. The first light-emitting layer lip is provided between the first segment electrode 11e and the first counter electrode 11f. The first segment intermediate layer 11q is provided between the first segment electrode 11e and the first light-emitting layer lip. The first counter intermediate layer 11r is provided between the first light-emitting layer 11p and the first counter electrode 11f. The first segment electrode 11e is included in the first light-emitting region 11. In the example, the first counter electrode 11f, the first light-emitting layer 11p, the first segment intermediate layer 11q, and the first counter intermediate layer 11r also are included in the first light-emitting region 11.

A second segment electrode 12e, a second counter electrode 12f, a second light-emitting layer 12p, a second segment intermediate layer 12q, and a second counter intermediate layer 12r are further provided in the sensor 110p. The second light-emitting layer 12p is provided between the second segment electrode 12e and the second counter electrode 12f. The second segment intermediate layer 12q is provided between the second segment electrode 12e and the second light-emitting layer 12p. The second counter intermediate layer 12r is provided between the second light-emitting layer 12p and the second counter electrode 12f. The second segment electrode 12e is included in the second light-emitting region 12. In the example, the second counter electrode 12f, the second light-emitting layer 12p, the second segment intermediate layer 12q, and the second counter intermediate layer 12r also are included in the second light-emitting region 12.

The first light-emitting layer lip is, for example, a first organic light-emitting layer; and the second light-emitting layer 12p is, for example, a second organic light-emitting layer.

As shown in FIG. 4B, a counter electrode 10f is provided in a sensor 110q. The first segment electrode lie, the first light-emitting layer 11p, the first segment intermediate layer 11q, and the first counter intermediate layer 11r also are provided. The first light-emitting layer lip is provided between the first segment electrode lie and the counter electrode 10f. The first counter intermediate layer 11r is provided between the first light-emitting layer 11p and the counter electrode 10f. The second segment electrode 12e, the second light-emitting layer 12p, the second segment intermediate layer 12q, and the second counter intermediate layer 12r are further provided. The second light-emitting layer 12p is provided between the second segment electrode 12e and the counter electrode 10f. The second counter intermediate layer 12r is provided between the second light-emitting layer 12p and the counter electrode 10f. The first segment electrode 11e is included in the first light-emitting region 11. In the example, the first light-emitting layer lip, the first segment intermediate layer 11q, and the first counter intermediate layer 11r also are included in the first light-emitting region 11. The second segment electrode 12e is included in the second light-emitting region 12. In the example, the second light-emitting layer 12p, the second segment intermediate layer 12q, and the second counter intermediate layer 12r also are included in the second light-emitting region 12. The counter electrode 10f includes a portion overlapping the first segment electrode 11e in the Z-axis direction. This portion is used as the first light-emitting region 11. The counter electrode 10f includes a portion overlapping the second segment electrode 12e in the Z-axis direction. This portion is used as the second light-emitting region 12.

As shown in FIG. 4C, a light-emitting layer 10p, a segment intermediate layer 10q, a counter intermediate layer 10r, and the counter electrode 10f are provided in a sensor 110r. The first segment electrode 11e and the second segment electrode 12e are further provided. The light-emitting layer 10p is provided between the first segment electrode 11e and the counter electrode 10f and between the second segment electrode 12e and the counter electrode 10f. The segment intermediate layer 10q is provided between the first segment electrode 11e and the light-emitting layer 10p and between the second segment electrode 12e and the counter electrode 10f. The counter intermediate layer 10r is provided between the light-emitting layer 10p and the counter electrode 10f. The first segment electrode lie is included in the first light-emitting region 11. The second segment electrode 12e is included in the second light-emitting region 12. The light-emitting layer 10p, the segment intermediate layer 10q, the counter intermediate layer 10r, and the counter electrode 10f respectively include portions overlapping the first segment electrode 11e in the Z-axis direction. These portions are used as the first light-emitting region 11. The light-emitting layer 10p, the segment intermediate layer 10q, the counter intermediate layer 10r, and the counter electrode 10f respectively include portions overlapping the second segment electrode 12e in the Z-axis direction. These portions are used as the second light-emitting region 12.

The first and second segment electrodes 11e and 12e include, for example, at least one of aluminum, silver, or gold. These electrodes may include, for example, an alloy of magnesium and silver.

The first and second counter electrodes 11f and 12f include, for example, ITO (Indium Tin Oxide). These electrodes may include, for example, a conductive polymer such as PEDOT:PSS, etc. These electrodes may include, for example, a metal (e.g., aluminum, silver, etc.). In the case where these electrodes include a metal, it is favorable for the thicknesses of these electrodes to be not less than 5 nm (nanometers) and not more than 20 nm. Thereby, light transmissivity is obtained.

The first and second segment intermediate layers 11q and 12q include, for example, at least one of Alq₃, BAlq, POPy₂, Bphen, or 3TPYMB. For example, these segment intermediate layers function as electron transport layers. These segment intermediate layers may include, for example, at least one of LiF, CsF, Ba, or Ca. For example, these segment intermediate layers may function as electron injection layers.

The first and second light-emitting layers 11p and 12p may include a mixed material containing a host material and a dopant added to the host material.

The host material includes, for example, at least one of CBP (4,4′-N,N′-bis dicarbazolyl-biphenyl), BCP (2,9-dimethyl-4,7 diphenyl-1,10-phenanthroline), TPD (-dimethyl-4,7 diphenyl-1,10-phenanthroline), PVK (polyvinyl carbazole), or PPT (poly(3-phenylthiophene)).

The dopant material includes, for example, at least one of Flrpic (iridium(III)-bis(4,6-di-fluorophenyl)-pyridinate-N,C2′-picolinate), Ir(ppy)₃ (tris(2-phenylpyridine)iridium), or Flr6 (bis(2,4-difluorophenylpyridinato)-tetrakis(1-pyrazolyl)borate-iridium(III)).

The first and second counter intermediate layers 11r and 12r include, for example, at least one of α-NPD, TAPC, m-MTDATA, TPD, or TCTA. For example, these counter intermediate layers function as hole transport layers. These counter intermediate layers may include, for example, at least one of PEDPOT:PPS, CuPc, or MoO₃. These counter intermediate layers may function as hole injection layers.

For example, the third to fifth light-emitting regions 13 to 15 have configurations similar to the first light-emitting region 11 or the second light-emitting region 12 recited above.

The first to fifth light-emitting regions 11 to 15 are, for example, OLEDs (Organic Light Emitting Diodes).

The substrate 80 includes, for example, glass. The thickness of the substrate 80 is, for example, not less than 0.05 mm and not more than 2.0 mm. The substrate 80 may include a resin.

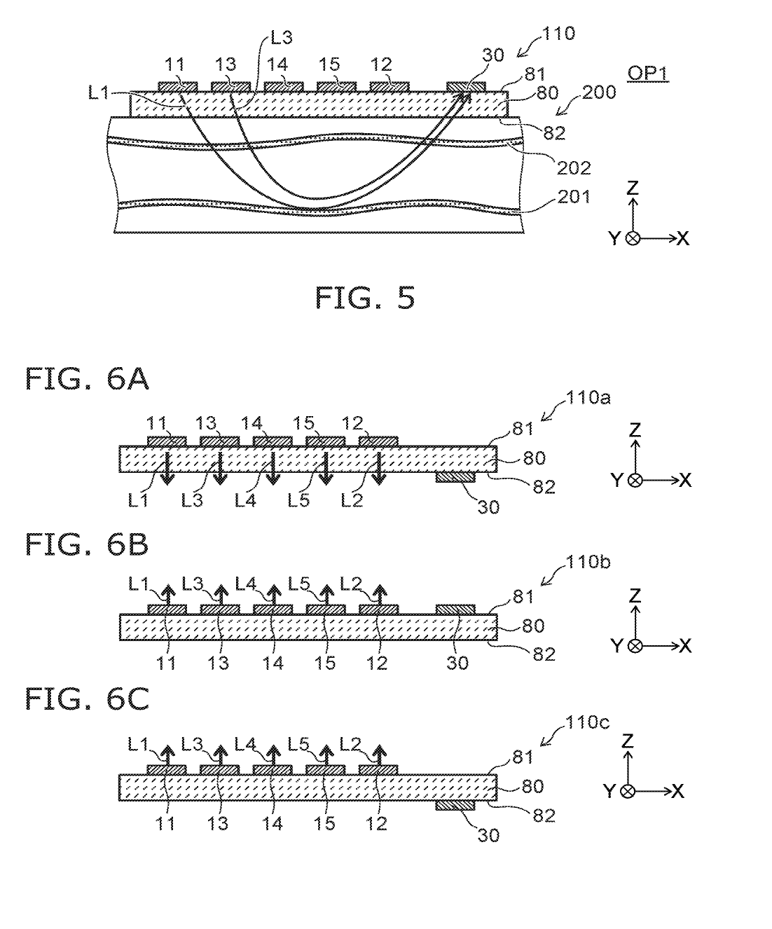

FIG. 5 is a schematic cross-sectional view illustrating another operation of the sensor according to the first embodiment.

FIG. 5 shows another example of the first operation OP1 implemented by the sensor 110.

The first light-emitting region 11, the second light-emitting region 12, and the third light-emitting region 13 are provided in the sensor 110. As described above, the third position of the third light-emitting region 13 in the first direction (the X-axis direction) is between the first position (the position of the first light-emitting region 11 in the first direction) and the second position (the position of the second light-emitting region 12 in the first direction). The third light-emitting region 13 is proximal to the first light-emitting region 11. The third light-emitting region 13 is distal to the second light-emitting region 12. The distance between the first position and the third position is shorter than the distance between the third position and the second position. In such a case, the following first operation OP1 is performed.

In the first operation OP1, the first light-emitting region 11 is in the light-emitting state; the second light-emitting region 12 is in the non-light-emitting state; and the third light-emitting region 13 is in the light-emitting state (a third light-emitting state). On the other hand, in the second operation OP2 as described in reference to FIG. 2B, the first light-emitting region 11 is in the non-light-emitting state; and the second light-emitting region 12 is in the light-emitting state. In the second operation OP2, the third light-emitting region 13 is in the non-light-emitting state (a third non-light-emitting state).

In other words, in the first operation OP1, the multiple light-emitting regions 10 are set to the light-emitting state in the regions (the first light-emitting region 11 and the third light-emitting region 13) distal to the light receiving element 30. On the other hand, in the second operation OP2, only the region (the second light-emitting region 12) proximal to the light receiving element 30 is set to the light-emitting state. The number of the light-emitting regions 10 set to the light-emitting state in the regions distal to the light receiving element 30 is larger than the number of the light-emitting regions 10 set to the light-emitting state in the regions proximal to the light receiving element 30.

For example, when sensing the first blood vessel 201 (the object at the deep position inside the living body 200), the intensity of the light reaching the light receiving element 30 is low compared to the second blood vessel 202 (the object at the shallow position inside the living body 200). At this time, the first blood vessel 201 is sensed using the light of the first light-emitting region 11 and the third light-emitting region 13. Thereby, light having the appropriate intensity can be incident on the light receiving element 30. High-precision sensing is possible.

In the embodiment, the multiple light-emitting regions may have mutually-different peak wavelengths. The intensity of the light emitted from the light-emitting region 10 has a maximum at the peak wavelength. For example, one of the multiple light-emitting regions 10 has a first peak wavelength. For example, one other of the multiple light-emitting regions 10 has the second peak wavelength.

The object of the sensing (e.g., the blood vessel) is sensed using two or more light-emitting regions 10 having different peak wavelengths. For example, the wavelength that has a high absorptance in the blood is different between different oxygen concentrations in the blood. By sensing the blood vessel using two or more light-emitting regions 10 having different peak wavelengths, for example, information relating to the oxygen concentration in the blood can be obtained. The applications of the sensor are expanded by using light of different wavelengths.

For example, the peak wavelength (the first peak wavelength) of the first light L1 emitted from the first light-emitting region 11 is different from the peak wavelength (the second peak wavelength) of the second light L2 emitted from the second light-emitting region 12. For example, in the first operation OP1, the first light-emitting region 11 is set to the light-emitting state; and the second light-emitting region 12 is set to the non-light-emitting state. Thereby, sensing is performed using the first peak wavelength. In the second operation OP2, the second light-emitting region 12 is set to the light-emitting state; and the first light-emitting region 11 is set to the non-light-emitting state. Thereby, sensing is performed using the second peak wavelength. The first light L1 of the first peak wavelength is irradiated on the object independently from the second light L2 of the second peak wavelength. Thereby, the characteristics that correspond to each peak wavelength can be sensed with high sensitivity. Thereby, high-precision sensing is possible.

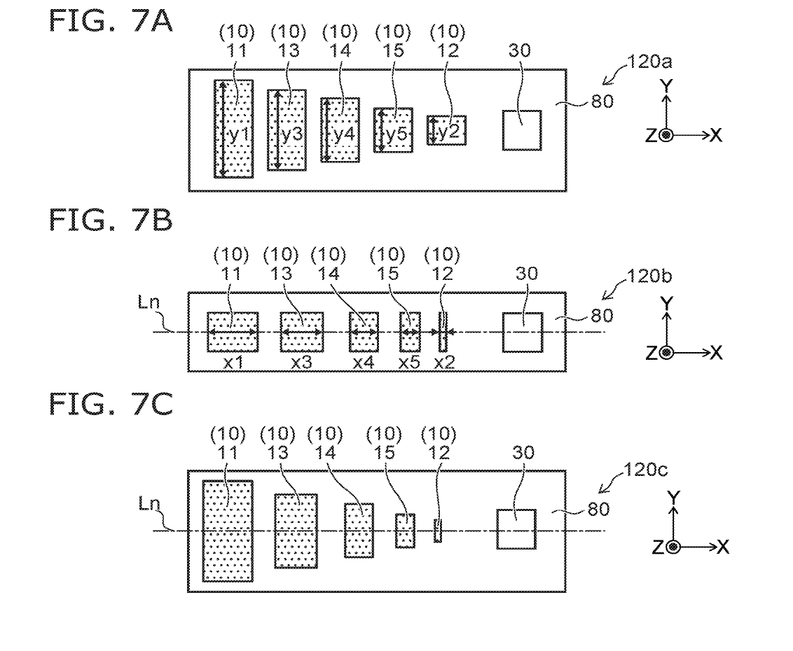

FIG. 6A to FIG. 6C are schematic cross-sectional views illustrating other sensors according to the first embodiment.

In a sensor 110a as shown in FIG. 6A, the light receiving element 30 is provided at the second surface 82 of the substrate 80. In a sensor 110b and a sensor 110c as shown in FIG. 6B and FIG. 6C, the light is emitted to the side opposite to the substrate 80. In the sensor 110b, the light receiving element 30 is provided at the first surface 81 of the substrate 80. In the sensor 110c, the light receiving element 30 is provided at the second surface 82 of the substrate 80. The sensors 110 and 110a are a bottom-emission type. The sensors 110b and 110c are a top-emission type.

Thus, in the embodiment, the first light-emitting region 11 and the second light-emitting region 12 are provided in the first surface 81 of the substrate 80. The light receiving element 30 is provided at one of the first surface 81 or the second surface 82.

### Second Embodiment

FIG. 7A to FIG. 7C are schematic plan views illustrating sensors according to a second embodiment.

In a sensor 120a as shown in FIG. 7A, the surface area of the first light-emitting region 11 is greater than the surface area of the second light-emitting region 12. The surface area of the third light-emitting region 13 is between the surface area of the first light-emitting region 11 and the surface area of the second light-emitting region 12. The surface area of the fourth light-emitting region 14 is between the surface area of the third light-emitting region 13 and the surface area of the second light-emitting region 12. The surface area of the fifth light-emitting region 15 is between the surface area of the fourth light-emitting region 14 and the surface area of the second light-emitting region 12.

In the sensor 120a, the surface area of the light-emitting region 10 increases as the distance from the light receiving element 30 increases and the distance (depth) to the object of the sensing increases. Thereby, even in the case where the object of the sensing is distal (deep) and the distance from the light receiving element 30 is long, the intensity of the light incident on the light receiving element 30 can be maintained to be high. Thereby, high-precision sensing is possible.

In the sensor 120a, a first length y1 of the first light-emitting region 11 along a second direction (a direction perpendicular to the first direction, i.e., the Y-axis direction) is longer than a second length y2 of the second light-emitting region 12 along the second direction. A third length y3 of the third light-emitting region 13 along the Y-axis direction is between the first length y1 and the second length y2. A fourth length y4 of the fourth light-emitting region 14 along the Y-axis direction is between the third length y3 and the second length y2. A fifth length y5 of the fifth light-emitting region 15 along the Y-axis direction is between the fourth length y4 and the second length y2.

As shown in FIG. 7B, in a sensor 120b as well, the surface area of the light-emitting region 10 increases as the distance from the light receiving element 30 increases.

Thereby, even in the case where the distance from the light receiving element 30 is long, the intensity of the light incident on the light receiving element 30 can be maintained to be high. Thereby, high-precision sensing is possible.

In the sensor 120b, a first width x1 of the first light-emitting region 11 along a straight line Ln (a straight line passing through the center of the light receiving element 30 along the first direction) is wider than a second width x2 of the second light-emitting region 12 along the straight line Ln. A third width x3 of the third light-emitting region 13 along the straight line Ln is between the first width x1 and the second width x2. A fourth width x4 of the fourth light-emitting region 14 along the straight line Ln is between the third width x3 and the second width x2. A fifth width x5 of the fifth light-emitting region 15 along the straight line Ln is between the fourth width x4 and the second width x2.

As shown in FIG. 7C, in a sensor 120c as well, the surface area of the light-emitting region 10 increases as the distance from the light receiving element 30 increases. Thereby, even in the case where the distance from the light receiving element 30 is long, the intensity of the light incident on the light receiving element 30 can be maintained to be high. Thereby, high-precision sensing is possible.

In the sensor 120c, the first length y1 is longer than the second length y2. The third length y3 of the third light-emitting region 13 along the Y-axis direction is between the first length y1 and the second length y2. The fourth length y4 of the fourth light-emitting region 14 along the Y-axis direction is between the third length y3 and the second length y2. The fifth length y5 of the fifth light-emitting region 15 along the Y-axis direction is between the fourth length y4 and the second length y2. The first width x1 is wider than the second width x2. The third width x3 of the third light-emitting region 13 along the straight line Ln is between the first width x1 and the second width x2. The fourth width x4 of the fourth light-emitting region 14 along the straight line Ln is between the third width x3 and the second width x2. The fifth width x5 of the fifth light-emitting region 15 along the straight line Ln is between the fourth width x4 and the second width x2.

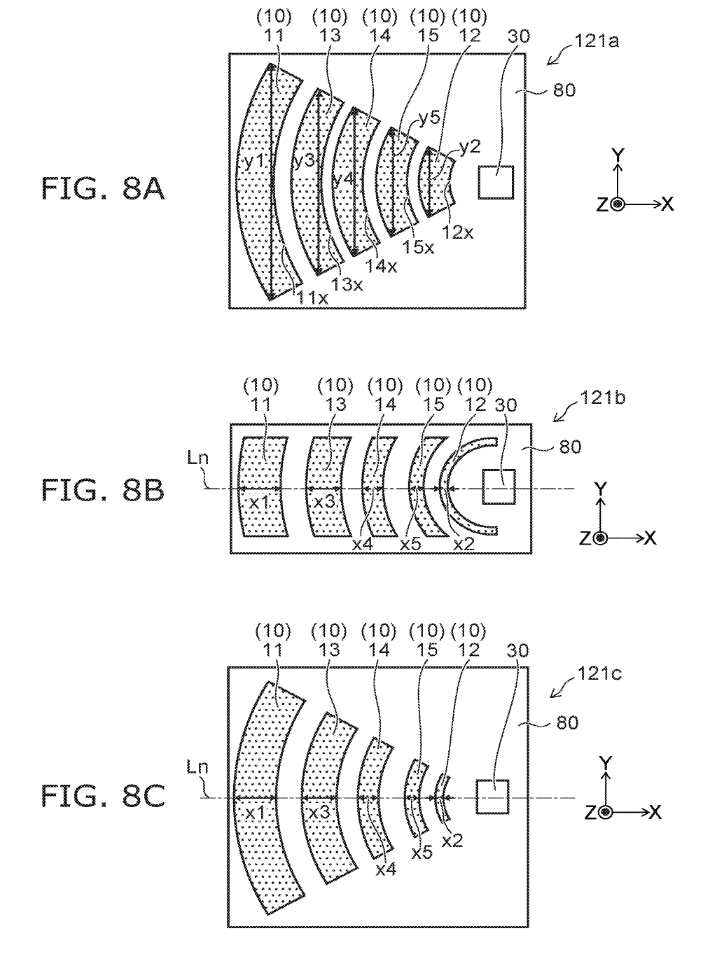

FIG. 8A to FIG. 8C are schematic plan views illustrating other sensors according to the second embodiment.

As shown in FIG. 8A to FIG. 8C, the multiple light-emitting regions 10 each have an arc configuration in sensors 121a, 121b, and 121c. In other words, the first light-emitting region 11 has a first edge portion 11x on the light receiving element 30 side. The first edge portion 11x is recessed along a direction (the −X direction) from the light receiving element 30 toward the first light-emitting region 11. Similarly, the second light-emitting region 12 has a second edge portion 12x on the light receiving element 30 side. The second edge portion 12x is recessed along the −X direction. The third light-emitting region 13 has a third edge portion 13x on the light receiving element 30 side. The third edge portion 13x is recessed along the −X direction. The fourth light-emitting region 14 has a fourth edge portion 14x on the light receiving element 30 side. The fourth edge portion 14x is recessed along the −X direction. The fifth light-emitting region 15 has a fifth edge portion 15x on the light receiving element 30 side. The fifth edge portion 15x is recessed along the −X direction.

The first to fifth edge portions 11x to 15x each include at least a portion of an arc having the light receiving position (the position of the light receiving element 30 in the first direction) as the center. At least a portion of the second edge portion 12x is parallel to at least a portion of the first edge portion 11x.

In these examples as well, the surface area of the first light-emitting region 11 is greater than the surface area of the second light-emitting region 12. The surface area of the third light-emitting region 13 is between the surface area of the first light-emitting region 11 and the surface area of the second light-emitting region 12. The surface area of the fourth light-emitting region 14 is between the surface area of the third light-emitting region 13 and the surface area of the second light-emitting region 12. The surface area of the fifth light-emitting region 15 is between the surface area of the fourth light-emitting region 14 and the surface area of the second light-emitting region 12.

In the sensor 121a, y1>y3>y4>y5>y2. In the sensor 121b, x1>x3>x4>x5>x2. In the sensor 121c, y1>y3>y4>y5>y2 and x1>x3>x4>x5>x2. In the sensors 121a, 121b, and 121c as well, high-precision sensing is possible.

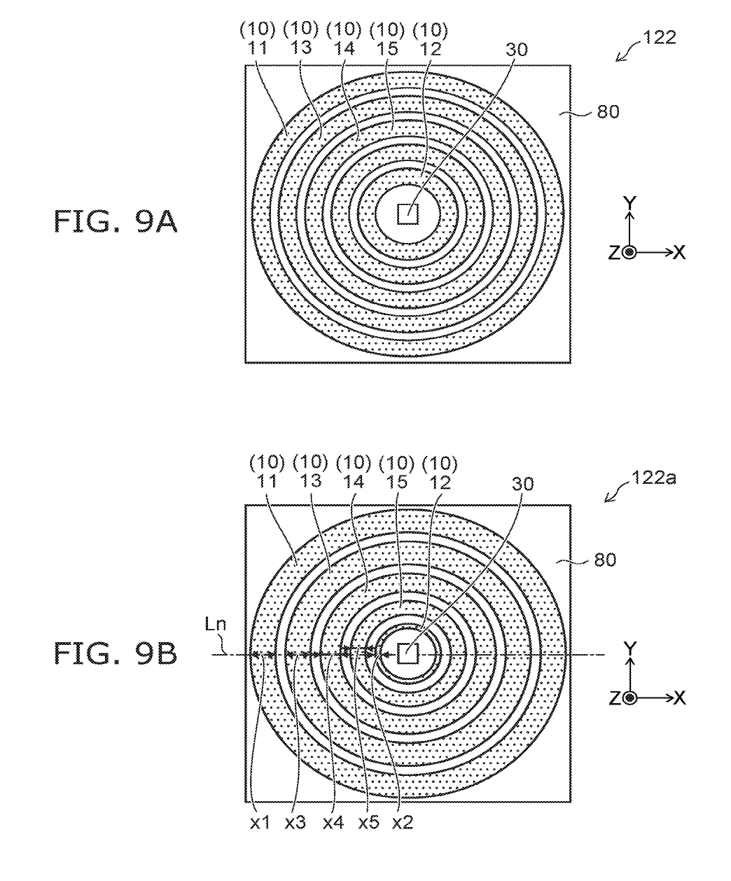

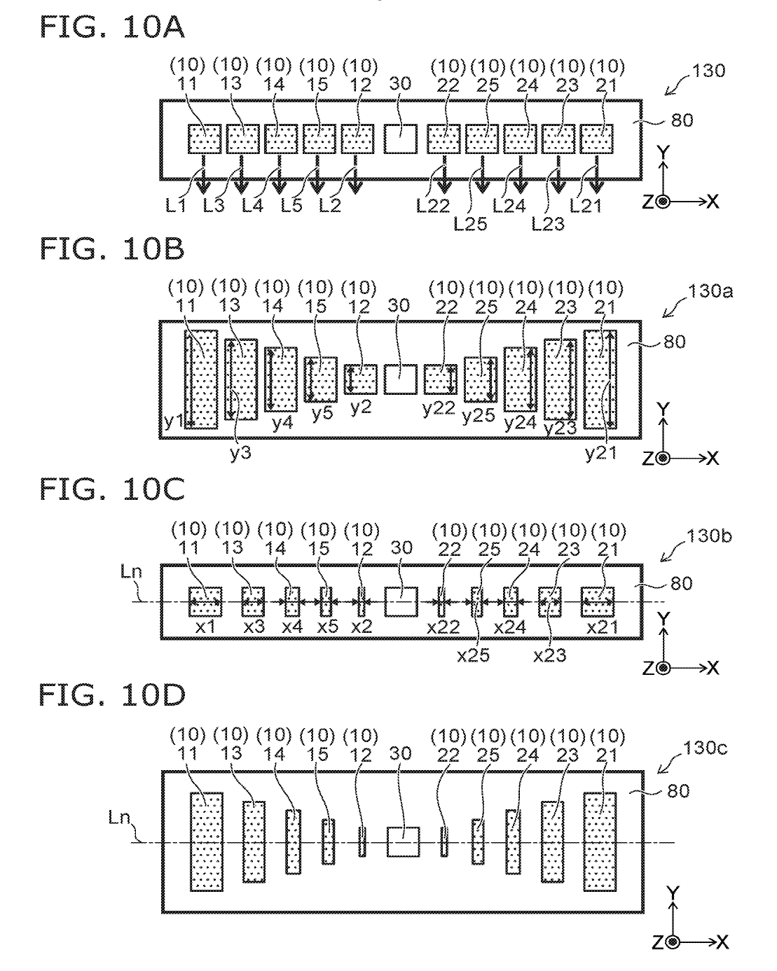

FIG. 9A and FIG. 9B are schematic plan views illustrating other sensors according to the second embodiment.

In sensors 122 and 122a as shown in FIG. 9A and FIG. 9B, the second light-emitting region 12 is provided around the light receiving element 30. The first light-emitting region 11 is provided around the second light-emitting region 12. The fifth light-emitting region 15 is provided around the second light-emitting region 12. The fourth light-emitting region 14 is provided around the fifth light-emitting region 15. The third light-emitting region 13 is provided around the fourth light-emitting region 14. The first light-emitting region 11 is provided around the third light-emitting region 13.

In the sensor 122, the first to fifth widths x1 to x5 are substantially the same. In the sensor 122a, x1>x3>x4>x5>x2. In the sensor 122 and the sensor 122a, the multiple light-emitting regions 10 have concentric circular configurations. The multiple light-emitting regions 10 each surround the light receiving element 30. The number of objects that can be sensed with high precision increases. In the sensors 122 and 122a as well, even in the case where the distance from the light receiving element 30 is long, the intensity of the light incident on the light receiving element 30 can be maintained to be high. Thereby, high-precision sensing is possible.

### Third Embodiment

FIG. 10A to FIG. 10D are schematic plan views illustrating other sensors according to a third embodiment.

As shown in FIG. 10A, a sensor 130 according to the embodiment further includes a first counter light-emitting region 21 and a second counter light-emitting region 22 in addition to the first light-emitting region 11, the second light-emitting region 12, and the light receiving element 30. In the example, the sensor 130 includes the third to fifth light-emitting regions 13 to 15. The sensor 130 includes third to fifth counter light-emitting regions 23 to 25. For example, the light receiving element 30 and the first to fifth light-emitting regions 11 to 15 are similar to those of the sensor 110. The first to fifth counter light-emitting regions 21 to 25 will now be described.

The position (a second counter position) of the second counter light-emitting region 22 in the first direction (the X-axis direction) is between the position (a first counter position) of the first counter light-emitting region 21 in the first direction and the first position (the position of the first light-emitting region 11 in the first direction). The second position (the position of the second light-emitting region 12 in the first direction) is between the first position and the second counter position. The light receiving position (the position of the light receiving element 30 in the first direction) is between the second counter position and the second position.

The position (a third counter position) of the third counter light-emitting region 23 in the first direction is between the first counter position and the second counter position. The position (a fourth counter position) of the fourth counter light-emitting region 24 in the first direction is between the third counter position and the second counter position. The position (a fifth counter position) of the fifth counter light-emitting region 25 in the first direction is between the fourth counter position and the second counter position.

At least a portion of a first counter light L21 emitted from the first counter light-emitting region 21 and at least a portion of a second counter light L22 emitted from the second counter light-emitting region 22 are incident on the light receiving element 30. At least a portion of a third counter light L23 emitted from the third counter light-emitting region 23, at least a portion of a fourth counter light L24 emitted from the fourth counter light-emitting region 24, and at least a portion of a fifth counter light L25 emitted from the fifth counter light-emitting region 25 are incident on the light receiving element 30.

In the sensor 130, for example, the multiple light-emitting regions 10 (the first to fifth light-emitting regions 11 to 15 and the first to fifth counter light-emitting regions 21 to 25) are provided around the light receiving element 30 as the center. The range of objects that can be sensed with high precision expands.

In a sensor 130a according to the embodiment as shown in FIG. 10B, y1>y3>y4>y5>y2. A first counter length y21 of the first counter light-emitting region 21 along the second direction (a direction perpendicular to the first direction, i.e., the Y-axis direction) is longer than a second counter length y22 of the second counter light-emitting region 22 along the second direction. A third counter length y23 of the third counter light-emitting region 23 along the Y-axis direction is between the first counter length y21 and the second counter length y22. A fourth counter length y24 of the fourth counter light-emitting region 24 along the Y-axis direction is between the third counter length y23 and the second counter length y22. A fifth counter length y25 of the fifth counter light-emitting region 25 along the Y-axis direction is between the fourth counter length y24 and the second counter length y22.

In a sensor 130b according to the embodiment as shown in FIG. 10C, x1>x3>x4>x5>x2. A first counter width x21 of the first counter light-emitting region 21 along the straight line Ln (a straight line passing through the center of the light receiving element 30 along the first direction) is wider than a second counter width x22 of the second counter light-emitting region 22 along the straight line Ln. A third counter width x23 of the third counter light-emitting region 23 along the straight line Ln is between the first counter width x21 and the second counter width x22. A fourth counter width x24 of the fourth counter light-emitting region 24 along the straight line Ln is between the third counter width x23 and the second counter width x22. A fifth counter width x25 of the fifth counter light-emitting region 25 along the straight line Ln is between the fourth counter width x24 and the second counter width x22.

In a sensor 130c according to the embodiment as shown in FIG. 10D, x1>x3>x4>x5>x2. Further, x21>x23>x24>x25>x22. y1>y3>y4>y5>y2. Further, y21>y23>y24>y25>y22.

In the sensors 130a to 130c, the surface area of the first counter light-emitting region 21 is greater than the surface area of the second counter light-emitting region 22. The surface area of the third counter light-emitting region 23 is between the surface area of the first counter light-emitting region 21 and the surface area of the second counter light-emitting region 22. The surface area of the fourth counter light-emitting region 24 is between the surface area of the third counter light-emitting region 23 and the surface area of the second counter light-emitting region 22. The surface area of the fifth counter light-emitting region 25 is between the surface area of the fourth counter light-emitting region 24 and the surface area of the second counter light-emitting region 22. Even in the case where the distance from the light receiving element 30 is long, the intensity of the light incident on the light receiving element 30 can be maintained to be high. Thereby, high-precision sensing is possible.

In the sensors 130a to 130c, the first to fifth counter light-emitting regions 21 to 25 have first to fifth counter edge portions on the light receiving element 30 side; and the first to fifth counter edge portions may be recessed along a direction from the light receiving element 30 toward the first counter light-emitting region 21. For example, the first to fifth counter edge portions each may include at least a portion of an arc having the light receiving position as a center. For example, at least a portion of the second counter edge portion may be parallel to at least a portion of the first counter edge portion.

### Fourth Embodiment

FIG. 11 is a schematic plan view illustrating a sensor according to a fourth embodiment.

As shown in FIG. 11, the sensor 140 according to the embodiment includes the multiple light-emitting regions 10 and the light receiving element 30. The multiple light-emitting regions 10 are arranged along the first direction (the X-axis direction) and the second direction (the Y-axis direction). The multiple light-emitting regions 10 are arranged in a matrix configuration. The first direction one of a column or a row. The second direction is the other of the column or the row. In the sensor 140, for example, one of the multiple light-emitting regions 10 is set to the light-emitting state; and one of the other light-emitting regions 10 is set to the non-light-emitting state. For example, the light-emitting regions 10 that are to be set to the light-emitting state are determined according to the target object of the sensing. The target object of the sensing can be sensed with higher precision.

In the second to fourth embodiments recited above as well, the multiple light-emitting regions 10 may have mutually-different peak wavelengths. For example, the peak wavelength (the first peak wavelength) of the first light L1 emitted from the first light-emitting region 11 is different from the peak wavelength (the second peak wavelength) of the second light L2 emitted from the second light-emitting region 12.

### Fifth Embodiment

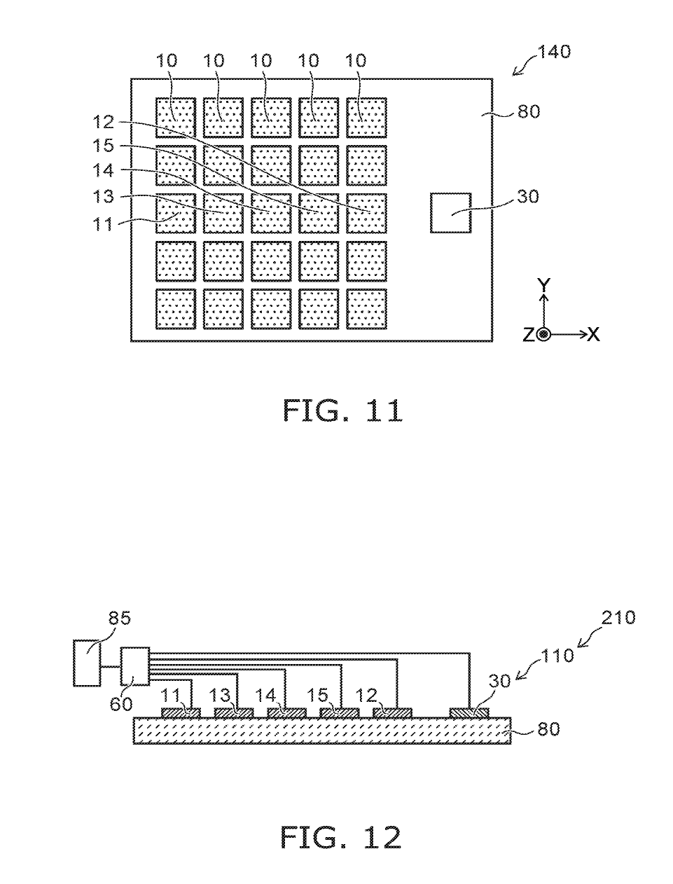

FIG. 12 is a schematic view illustrating a sensor system according to a fifth embodiment.

As shown in FIG. 12, the sensor system 210 according to the embodiment includes the sensor 110 and an interface unit 85. The interface unit 85 supplies the sense signal sensed by the sensor 110 to the outside. The interface unit 85 may acquire a control signal from the outside and supply the control signal to the controller 60. The sensors according to the first to fourth embodiments and modifications of the first to fourth embodiments may be used as the sensor.

For example, the sensors according to the first to fourth embodiments and the sensor system according to the fifth embodiment recited above are applicable to the sensing of the pulse wave of a living body.

For example, in the field of medicine, the pulse waveform (e.g., the pulse waveform of an artery) is measured. For example, the analysis of the pulse wave is performed in an examination of the circulatory system (e.g., an arteriosclerosis level measurement or a stress level measurement). For example, the analysis of the pulse wave is performed also by a pulse oximeter (arterial oxygen saturation measuring device).

For example, technology is being developed to constantly measure the pulse wave by using portable measuring devices such as a wristwatch-type device, a device adhered to the living body, etc. For example, in photoplethysmography, the waveform of the pulse wave is measured percutaneously without paracentesis or drawing blood. In such a method, it is possible to suppress the burden on the living body and perform the measurement easily. Therefore, there are expectations for a wide range of applications in the field of health care. For example, the blood pressure is estimated by calculating the acceleration pulse wave from the waveform of the pulse wave and analyzing the characteristic points of acceleration pulse wave.

For example, in the field of medicine, a photoplethysmograph measuring device is mounted to a finger tip or an ear lobe; light is irradiated on the living body; and the light that passes through the living body is sensed. On the other hand, the photoplethysmograph measuring device that is constantly mounted to the finger tip or the ear lobe is inappropriate for applications in the field of health care because the burden is large. Wristwatch-type measuring devices are being developed from this perspective. However, compared to a finger tip or an ear lobe, the density of the blood vessels is low and the signal of the pulse wave is weak for the wrist, the chest, etc. If the density of the blood vessels is low, it is difficult to measure the waveform of the pulse wave with high precision.

In the embodiments recited above, the pulse wave can be sensed with high precision at the wrist, the chest, etc., where the blood vessel density is low. Because multiple light-emitting regions are provided, the load of one light-emitting region can be reduced.

In the embodiments, the multiple light-emitting regions are arranged in a lattice configuration. The multiple light-emitting regions emit, onto a measurement region of at least a portion of the living body, at least one type of measurement light belonging to a prescribed wavelength band. A light receiving element is provided. The measurement light that is emitted from the multiple light-emitting regions and passes through the living body is sensed by the light receiving element. For example, as the multiple light-emitting regions, an array of light sources (light-emitting regions) such as OLEDs, etc., are used. Such a configuration is less expensive than using a light receiving element array having a large surface area. The drive circuit is simpler for an array of light-emitting regions than for an array of light receiving elements. Low noise and a high S/N ratio are obtained by using OLEDs. In such a case, the driving time and luminance of one light source can be suppressed by using the array of OLED light sources. Thereby, a long life is obtained.

In the sensing method according to the embodiments, for example, the sensing is performed using multiple light sources (light-emitting regions) and a light receiving element. The multiple light sources emit, onto the measurement region of at least a portion of the living body, at least one type of measurement light belonging to a prescribed wavelength band. The multiple light sources are arranged in a lattice configuration. The measurement light that is emitted from the multiple light sources and passes through the living body is sensed by the light receiving element. In the sensing method, the analysis processing is performed based on the temporal change of the light amount of the measurement light that is sensed. The analysis processing includes designating the measurement position inside the measurement region. The measurement position is used to measure information relating to the pulsatory motion accompanying the activity of the living body.

A program according to the embodiments causes a computer to implement the sensing method recited above. The program recited above is recorded in a recording medium according to the embodiments.

According to the embodiments, a sensor and a sensor system are provided in which the sensing precision can be increased.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in sensors such as light emitting regions, light receiving elements, substrates, organic light emitting layers, electrodes, controllers, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all sensors and sensor systems practicable by an appropriate design modification by one skilled in the art based on the sensors and the sensor systems described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A sensor, comprising:
a first light-emitting region to emit a first light;
a second light-emitting region to emit a second light; and
a light receiving element, at least one of at least a portion of the first light or at least a portion of the second light being incident on the light receiving element,
a second position of the second light-emitting region in a first direction being between a first position of the first light-emitting region in the first direction and a light receiving position of the light receiving element in the first direction, the first direction being from the first light-emitting region toward the second light-emitting region.

2. The sensor according to claim 1, wherein a surface area of the first light-emitting region is greater than a surface area of the second light-emitting region.

3. The sensor according to claim 1, wherein a first length of the first light-emitting region along a second direction is longer than a second length of the second light-emitting region along the second direction, the second direction being perpendicular to the first direction.

4. The sensor according to claim 1, wherein a first width of the first light-emitting region along a straight line is wider than a second width of the second light-emitting region along the straight line, the straight line being along the first direction and passing through a center of the light receiving element.

5. The sensor according to claim 1, wherein
the first light-emitting region has a first edge portion on a side of the light receiving element, and
the first edge portion is recessed along a direction, the direction being from the light receiving element toward the first light-emitting region.

6. The sensor according to claim 1, wherein
the first light-emitting region has a first edge portion on a side of the light receiving element, and
the first edge portion includes at least a portion of an arc having the light receiving position as a center.

7. The sensor according to claim 6, wherein
the second light-emitting region has a second edge portion on a side of the light receiving element, and
the second edge portion includes at least a portion of an arc having the light receiving position as a center.

8. The sensor according to claim 7, wherein
at least a portion of the second edge portion is parallel to at least a portion of the first edge portion.

9. The sensor according to claim 1, wherein
the second light-emitting region is provided around the light receiving element.

10. The sensor according to claim 1, wherein
the first light emitting region is provided around the second light-emitting region.

11. The sensor according to claim 1, further comprising:
a first counter light-emitting region; and
a second counter light-emitting region,
a second counter position of the second counter light-emitting region in the first direction being between the first position and a first counter position of the first counter light-emitting region in the first direction,
the second position being between the first position and the second counter position,
the light receiving position being between the second position and the second counter position.

12. The sensor according to claim 11, wherein a surface area of the first counter light-emitting region is greater than a surface area of the second counter light-emitting region.

13. The sensor according to claim 1, wherein a peak wavelength of the first light emitted from the first light-emitting region is different from a peak wavelength of the second light emitted from the second light-emitting region.

14. The sensor according to claim 1, further comprising a controller to control the first light-emitting region and the second light-emitting region,
wherein
the controller implements a first operation and a second operation,
in the first operation, the first light-emitting region is in a first light-emitting state, and the second light-emitting region is in a second non-light-emitting state,
in the second operation, the first light-emitting region is in a first non-light-emitting state, and the second light-emitting region is in a second light-emitting state.

15. The sensor according to claim 14, wherein
the first light-emitting region does not emit light in the first non-light-emitting state, or
an intensity of the light emitted from the first light-emitting region in the first non-light-emitting state is lower than an intensity of the light emitted from the first light-emitting region in the first light-emitting state.

16. The sensor according to claim 14, further comprising a third light-emitting region,
a third position of the third light-emitting region in the first direction being between the first position and the second position,
the third light-emitting region being in a third light-emitting state in the first operation,
the third light-emitting region being in a third non-light-emitting state in the second operation.

17. The sensor according to claim 16, wherein
a length between the first position and the third position is shorter than a length between the third position and the second position.

18. The sensor according to claim 1, further comprising a substrate,
the substrate having a first surface and a second surface, the first surface being along the first direction, the second surface being on a side opposite to the first surface,
the first light-emitting region and the second light-emitting region being provided in the first surface,
the light receiving element being provided in one of the first surface or the second surface.

19. The sensor according to claim 1, wherein
The first light-emitting region includes a first organic light-emitting layer, and
The second light-emitting region includes a second organic light-emitting layer.

20. A sensor system comprising:
a sensor; and
an interface unit supplying a sense signal sensed by the sensor to outside,
the sensor including
a first light-emitting region to emit a first light,
a second light-emitting region to emit a second light, and
a light receiving element, at least one of at least a portion of the first light or at least a portion of the second light being incident on the light receiving element,
a second position of the second light-emitting region in a first direction being between a first position of the first light-emitting region in the first direction and a light receiving position of the light receiving element in the first direction, the first direction being from the first light-emitting region toward the second light-emitting region.
